(19) United States
(12) Patent Application Publication
(10) Pub. No.: US 2026/0165146 A1
(43) Pub. Date: Jun. 11, 2026

(54) SEMICONDUCTOR PACKAGE AND METHOD OF FABRICATING THE SAME

(71) Applicant: SAMSUNG ELECTRONICS CO., LTD., Suwon-si (KR)

(72) Inventors: SEUNGWAN SHIN, Suwon-si (KR); KYUNGSEOB OH, Suwon-si (KR)

(73) Assignee: SAMSUNG ELECTRONICS CO., LTD., Suwon-si (KR)

(21) Appl. No.: 19/319,186

(22) Filed: Sep. 4, 2025

(30) Foreign Application Priority Data
Dec. 10, 2024 (KR) 10-2024-0182592

(51) Int. Cl. H01L 23/544; H01L 23/31; H01L 23/538

(52) U.S. Cl. CPC H10W 46/00; H10W 70/614; H10W 74/117

(57) ABSTRACT

A semiconductor package includes a first redistribution substrate; a semiconductor device on the first redistribution substrate; a mold layer that covers the first redistribution substrate and the semiconductor device; and a second redistribution substrate on the mold layer. The second redistribution substrate includes a first redistribution dielectric layer; a first redistribution pattern on the first redistribution dielectric layer; a marking pattern on the first redistribution dielectric layer and spaced apart from the redistribution pattern; and a second redistribution dielectric layer that covers the marking pattern. A bottom surface of the marking pattern and a bottom surface of the first redistribution pattern are at a same level. A top surface of the marking pattern is at a level which is lower than a level of a top surface of the first redistribution pattern.

### CROSS-REFERENCE TO RELATED APPLICATION

This application claims priority under 35 U.S.C § 119 to Korean Patent Application No. 10-2024-0182592, filed on Dec. 10, 2024 in the Korean Intellectual Property Office, the disclosure of which is incorporated by reference herein in its entirety.

### BACKGROUND

The present disclosure relates to a semiconductor package and a method of fabricating the same.

A semiconductor package may be provided to implement an integrated circuit chip for use in electronic products. A semiconductor package is typically configured such that a semiconductor chip is mounted on a printed circuit board (PCB) and bonding wires, or bumps, are used to electrically connect the semiconductor chip to the printed circuit board. With the development of electronic industry, various research has been conducted to improve the reliability and the durability of semiconductor packages.

### SUMMARY

One or more example embodiments provide a highly integrated semiconductor package.

One or more example embodiments provide a method of fabricating the semiconductor package.

According to an aspect of the disclosure, a semiconductor package may include: a first redistribution substrate; a semiconductor device on the first redistribution substrate; a mold layer that covers the first redistribution substrate and the semiconductor device; and a second redistribution substrate on the mold layer, wherein the second redistribution substrate includes: a first redistribution dielectric layer; a redistribution pattern on the first redistribution dielectric layer; a marking pattern on the first redistribution dielectric layer and spaced apart from the redistribution pattern; and a second redistribution dielectric layer that covers the marking pattern, wherein a bottom surface of the marking pattern and a bottom surface of the redistribution pattern are at a same level, and wherein a top surface of the marking pattern is at a level which is lower than a level of a top surface of the redistribution pattern.

According to an aspect of the disclosure, a semiconductor package may include: a first redistribution substrate; a semiconductor device on the first redistribution substrate; a mold layer that covers the first redistribution substrate and the semiconductor device; and a second redistribution substrate on the mold layer, wherein the second redistribution substrate includes: a first redistribution dielectric layer; a redistribution pattern on the first redistribution dielectric layer; a marking pattern on the first redistribution dielectric layer and spaced apart from the redistribution pattern; and a second redistribution dielectric layer that covers the marking pattern, wherein the second redistribution dielectric layer is transparent, and wherein a thickness of the marking pattern is less than a thickness of the redistribution pattern.

According to an aspect of the disclosure, a semiconductor package may include: a first redistribution substrate; a plurality of external connection terminals bonded to a lower portion of the first redistribution substrate; a semiconductor device on the first redistribution substrate; a mold layer that covers the first redistribution substrate and the semiconductor device; a second redistribution substrate on the mold layer; and a connection member in the mold layer and connecting the first redistribution substrate to the second redistribution substrate, wherein the second redistribution substrate includes: a first redistribution dielectric layer; a redistribution pattern on the first redistribution dielectric layer; a marking pattern on the first redistribution dielectric layer and spaced apart from the redistribution pattern; and a second redistribution dielectric layer that covers the marking pattern, wherein the first redistribution dielectric layer and the second redistribution dielectric layer are transparent, wherein the marking pattern includes a marking region and a non-marking region, and wherein a surface roughness of a top surface of the marking region is different from a surface roughness of a top surface of the non-marking region.

According to an aspect of the disclosure, a method of fabricating a semiconductor package may include: forming a first redistribution pattern; forming a first redistribution dielectric layer having a hole that exposes a top surface of the first redistribution pattern; forming a seed layer on a top surface of the first redistribution dielectric layer and on the exposed top surface of the first redistribution pattern; forming, on the seed layer, a first mask pattern having an opening that overlaps the hole; performing a plating process to form a second redistribution pattern in the opening and the hole; removing the first mask pattern to expose the seed layer; forming a second mask pattern that covers a portion of the seed layer and that is spaced apart from the second redistribution pattern; removing the seed layer provided between a side of the second mask pattern and a side of the second redistribution pattern to expose the first redistribution dielectric layer and to form a marking pattern with the portion of the seed layer covered by the second mask pattern; removing the second mask pattern; forming a second redistribution dielectric layer that covers the marking pattern, the second redistribution pattern, and the first redistribution dielectric layer; and irradiating a laser to pass through the second redistribution dielectric layer to form a mark on the marking pattern.

The method of fabricating the semiconductor package may further include: forming the second redistribution dielectric layer, wherein the second redistribution dielectric layer is transparent.

The method of fabricating the semiconductor package may further include: removing the seed layer provided between the side of the second mask pattern and the side of the second redistribution pattern to expose the first redistribution dielectric layer and to form the marking pattern, wherein the marking pattern includes a plurality of grooves on a top surface of the marking pattern.

The method of fabricating the semiconductor package may further include: removing the seed layer provided between the side of the second mask pattern and the side of the second redistribution pattern to expose the first redistribution dielectric layer and to form the marking pattern, wherein the marking pattern includes a plurality of grooves on a top surface of the marking pattern, wherein the marking pattern has a first thickness, and wherein each one of the plurality of grooves has a depth that is about 0.1 to 0.5 times the first thickness.

The method of fabricating the semiconductor package may further include: removing the seed layer provided between the side of the second mask pattern and the side of the second redistribution pattern to expose the first redistribution dielectric layer and to form the marking pattern, wherein the marking pattern includes a plurality of grooves on a top surface of the marking pattern, wherein a floor of each one of the plurality of grooves is spaced apart from a bottom surface of the second redistribution dielectric layer.

The method of fabricating the semiconductor package may further include: removing the seed layer provided between the side of the second mask pattern and the side of the second redistribution pattern to expose the first redistribution dielectric layer and to form the marking pattern, wherein the marking pattern includes a marking region and a non-marking region, and wherein a surface roughness of a top surface of the marking region is different from a surface roughness of a top surface of the non-marking region.

The method of fabricating the semiconductor package may further include: removing the seed layer provided between the side of the second mask pattern and the side of the second redistribution pattern to expose the first redistribution dielectric layer and to form the marking pattern, wherein the marking pattern and the first redistribution pattern include a same material.

The method of fabricating the semiconductor package may further include: forming an adhesive pattern between the first redistribution pattern and the first redistribution dielectric layer, wherein the first redistribution pattern includes a first metal, and wherein the marking pattern and the adhesive pattern include a second metal different from the first metal.

The method of fabricating the semiconductor package may further include: forming an adhesive pattern between the first redistribution pattern and the first redistribution dielectric layer, wherein the first redistribution pattern includes a first metal, wherein the marking pattern and the adhesive pattern include a second metal different from the first metal, and wherein a thickness of the marking pattern equals a thickness of the adhesive pattern.

The method of fabricating the semiconductor package may further include: forming a first redistribution substrate; forming a second redistribution substrate; forming a mold layer and forming a mold via that penetrates the mold layer and that connects the first redistribution substrate to the second redistribution substrate.

The method of fabricating the semiconductor package may further include: forming a first redistribution substrate; forming a connection substrate on the first redistribution substrate; forming a mold layer; and forming a semiconductor device on the first redistribution substrate, wherein the semiconductor device is inserted into a cavity of the connection substrate, and wherein the mold layer covers the connection substrate.

### BRIEF DESCRIPTION OF DRAWINGS

The above and other aspects and features will be more apparent from the following description of one or more example embodiments taken in conjunction with the accompanying drawings, in which:

FIG. 1 illustrates a top plan view showing a semiconductor package according to one or more example embodiments;

FIG. 2 illustrates a cross-sectional view taken along line A-A′ of FIG. 1 according to one or more example embodiments;

FIGS. 3A and 3B illustrate enlarged views showing section P1 of FIG. 2 according to one or more example embodiments;

FIGS. 4A and 4B illustrate enlarged views showing section P1 of FIG. 2 according to one or more example embodiments;

FIGS. 5A, 5B, 5C, 5D, 5E, 5F, 5G, 5H, 5I and 5J illustrate cross-sectional views showing a method of fabricating a semiconductor package of FIG. 3A, according to one or more example embodiments;

FIG. 6 illustrates a cross-sectional view showing a semiconductor package according to one or more example embodiments;

FIG. 7 illustrates a cross-sectional view showing a semiconductor package according to one or more example embodiments;

FIG. 8 illustrates a cross-sectional view showing a semiconductor package according to one or more example embodiments;

FIG. 9 illustrates a bottom plan view showing a semiconductor package according to one or more example embodiments; and

FIG. 10 illustrates a cross-sectional view taken along line B-B′ of FIG. 9 according to one or more example embodiments;

### DETAILED DESCRIPTION

Hereinafter, one or more example embodiments will be described in detail with reference to the accompanying drawings to aid in clearly explaining one or more example embodiments. In this description, such terms as “first” and “second” may be used to simply distinguish identical or similar components from each other, and the sequence of such terms may be changed in accordance with the order of mention.

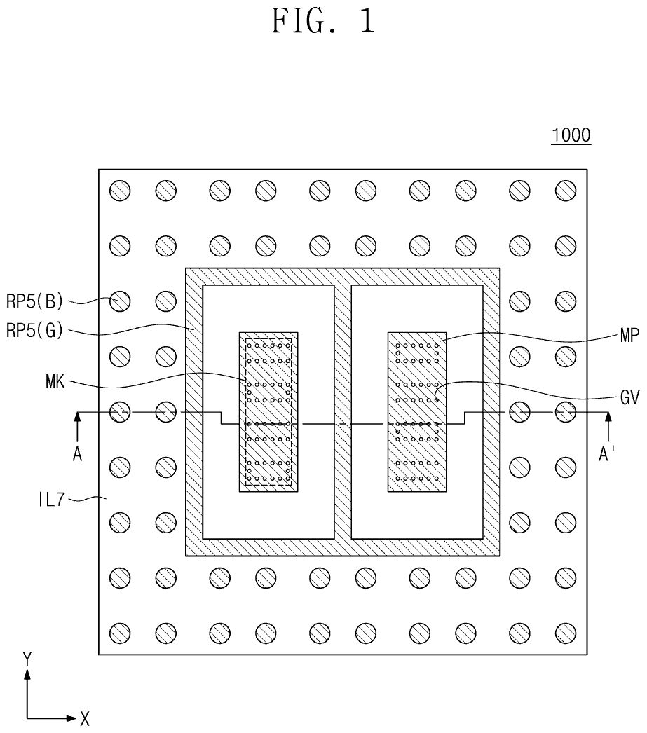

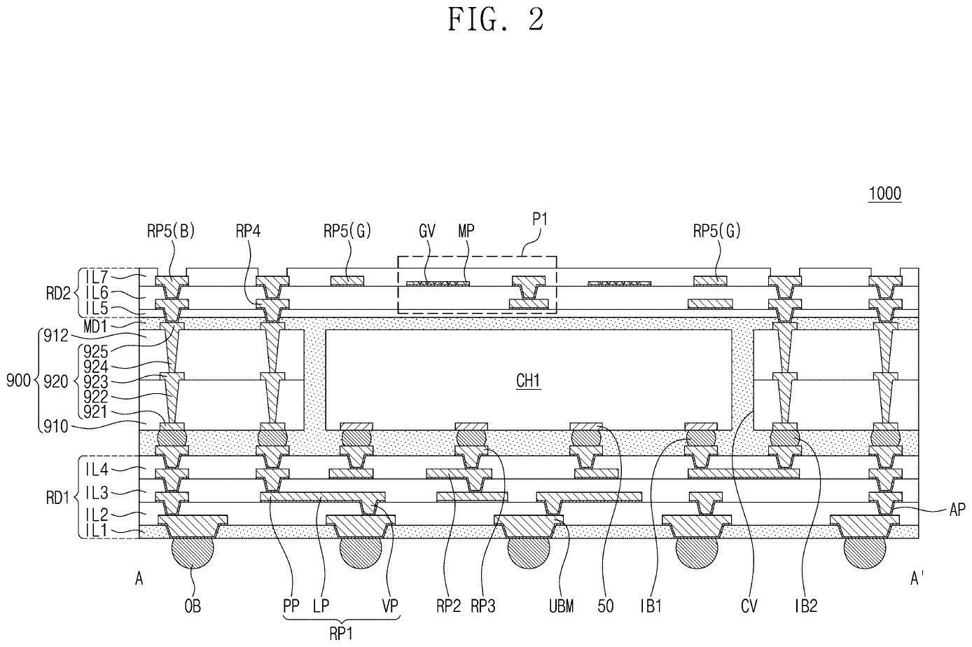

FIG. 1 illustrates a top plan view showing a semiconductor package according to one or more example embodiments. FIG. 2 illustrates a cross-sectional view taken along line A-A′ of FIG. 1 according to one or more example embodiments.

Referring to FIGS. 1 and 2, a semiconductor package 1000 according to one or more example embodiments may include a first redistribution substrate RD1, a first semiconductor device CH1, a connection substrate 900, a first mold layer MD1, and a second redistribution substrate RD2. The first semiconductor device CH1 and the connection substrate 900 may be mounted on the first redistribution substrate RD1. The connection substrate 900 may include a cavity CV into which the first semiconductor device CH1 is inserted. The first mold layer MD1 may cover the connection substrate 900, the first semiconductor device CH1, and the first redistribution substrate RD1. The second redistribution substrate RD2 may be disposed on the first mold layer MD1.

The first redistribution substrate RD1 may include first, second, third, and fourth redistribution dielectric layers IL1, IL2, IL3, and IL4 that are sequentially stacked. The first redistribution dielectric layer IL1 may be formed of an ajinomoto build-up film (ABF) or a photo-imageable dielectric (PID) layer. The first redistribution dielectric layer IL1 may be opaque or transparent. Each of the second, third and fourth redistribution dielectric layers IL2, IL3 and IL4 may be formed of a PID layer and may be transparent.

Under bumps UBM may be disposed in the first redistribution dielectric layer IL1. Each of the under bumps UBM may protrude into the first redistribution dielectric layer IL1 and may be covered with the second redistribution dielectric layer IL2. First redistribution patterns RP1 may be disposed between the second redistribution dielectric layer IL2 and the third redistribution dielectric layer IL3. Each of the first redistribution patterns RP1 may include a via part VP that penetrates the second redistribution dielectric layer IL2, and may also include a line part LP and a pad part PP on the second redistribution dielectric layer IL2. Second redistribution patterns RP2 may be disposed between the third redistribution dielectric layer IL3 and the fourth redistribution dielectric layer IL4. Each of the second redistribution patterns RP2 may include a via part VP that penetrates the third redistribution dielectric layer IL3, and may also include a line part LP and a pad part PP on the third redistribution dielectric layer IL3. Third redistribution patterns RP3 may be disposed on the fourth redistribution dielectric layer IL4. Each of the third redistribution patterns RP3 may include a via part VP that penetrates the fourth redistribution dielectric layer IL4 and a pad part P on the fourth redistribution dielectric layer IL4. The via parts VP may have inclined sidewalls whose width decreases in a downward direction.

The under bumps UBM and the first, second and third redistribution patterns RP1, RP2 and RP3 may each include copper. The under bumps UBM and the first, second and third redistribution patterns RP1, RP2 and RP3 may each have a bottom surface covered with an adhesive pattern AP. The adhesive pattern AP may include, for example, titanium.

An external connection terminal OB may be bonded to the under bump UBM. The external connection terminal OB may include at least one selected from: a solder ball, a conductive bump, and a conductive pillar. The external connection terminal OB may include at least one selected from: tin, lead, aluminum, gold, and nickel.

The first semiconductor device CH1 may be one semiconductor die or one semiconductor chip, or may be a semiconductor package including a plurality of the same or different kinds of semiconductor dies. The first semiconductor device CH1 may be one selected from: a microelectromechanical system (MEMS) device chip, an application specific integrated circuit (ASIC) chip, and a memory device chip such as Flash memory, Dynamic Random-Access Memory (DRAM), Static Random-Access Memory (SRAM), Electrically Erasable Programmable Read-Only Memory (EEPROM), parallel random-access machine (PRAM), Magnetoresistive Random-Access Memory (MRAM), Resistive Random-Access Memory (ReRAM), high bandwidth memory (HBM), and hybrid memory cubic (HMC).

Chip pads 50 may be disposed on a bottom end of the first semiconductor device CH1. The chip pads 50 may include a conductive material, such as copper or aluminum. The first semiconductor device CH1 may be flip-chip mounted through first inner connection members IB1 on the first redistribution substrate RD1. The first inner connection members IB1 may electrically connect the chip pads 50 of the first semiconductor device CH1 to some of the third redistribution patterns RP3. It is depicted in FIG. 2 that one first semiconductor device CH1 is mounted on the first redistribution substrate RD1, but embodiments are not limited thereto and, according to one or more example embodiments, a plurality of first semiconductor devices CH1 may be mounted on the first redistribution substrate RD1.

The connection substrate 900 may include a plurality of base layers 910 and 912 and a conductive structure 920. The base layers 910 and 912 may include, for example, a first base layer 910 and a second base layer 912 that constitute a two-story structure. The base layers 910 and 912 may include three or more stacked base layers. The base layers 910 and 912 may include a dielectric material. For example, the base layers 910 and 912 may include a carbon-based material, a ceramic, or a polymer.

The conductive structure 920 may include a connection pad 921, a first connection via 922, a first connection line 923, a second connection via 924, and a second connection line 925. In one or more example embodiments, the first connection via 922 and the first connection line 923 may be integrally formed into a single unitary piece. The second connection via 924 and the second connection line 925 may be integrally formed into a single unitary piece. The conductive structure 920 may include metal, such as copper, aluminum, gold, nickel, or titanium.

The connection substrate 900 may be flip-chip mounted through second inner connection members IB2 on the first redistribution substrate RD1. The second inner connection members IB2 may electrically connect the connection pads 921 of the connection substrate 900 to ones of the third redistribution patterns RP3. The first semiconductor device CH1 may be connected to the connection substrate 900 through at least one of the first, second and third redistribution patterns RP1, RP2 and RP3 of the first redistribution substrate RD1.

Each of the first and second inner connection members IB1 and IB2 may include at least one selected from: solder balls, conductive bumps, and conductive pillars. Each of the first and second inner connection members IB1 and IB2 may include at least one selected from: tin, lead, silver, aluminum, gold, and nickel.

The first mold layer MD1 may cover a sidewall and a top surface of the first semiconductor device CH1, a top surface and an inner lateral surface of the connection substrate 900, and a top surface of the first redistribution substrate RD1. The first mold layer MD1 may include a dielectric resin, such as an epoxy molding compound (EMC). The first mold layer MD1 may further include fillers, and the fillers may be dispersed in the dielectric resin. The first mold layer MD1 may fill a space between the first semiconductor device CH1 and the connection substrate 900.

The second redistribution substrate RD2 may include fifth, sixth, and seventh redistribution dielectric layers IL5, IL6, and IL7 that are sequentially stacked. The fifth, sixth, and seventh redistribution dielectric layers IL5, IL6, and IL7 may each include a photo-imageable dielectric (PID) layer. The fifth, sixth, and seventh redistribution dielectric layers IL5, IL6, and IL7 may all be transparent. The fifth, sixth, and seventh redistribution dielectric layers IL5, IL6, and IL7 may comprise a photo-imageable dielectric material. A fourth redistribution pattern RP4 may be interposed between the fifth redistribution dielectric layer IL5 and the sixth redistribution dielectric layer IL6. Fifth redistribution patterns RP5 and a marking pattern MP may be interposed between the sixth redistribution dielectric layer IL6 and the seventh redistribution dielectric layer IL7. The fifth redistribution patterns RP5 and the marking pattern MP may have their bottom surfaces covered with an adhesive pattern AP. The marking pattern MP may be positioned below an uppermost one IL7 among the fifth, sixth, and seventh redistribution dielectric layers IL5, IL6, and IL7 of the second redistribution substrate RD2.

The fifth redistribution patterns RP5 may include fifth redistribution patterns RP5(B) for bonding pads and a fifth redistribution pattern RP5(G) for a ground grid pattern. The seventh redistribution dielectric layer IL7 may expose top surfaces of the fifth redistribution patterns RP5(B) for bonding pads. The seventh redistribution dielectric layer IL7 may cover the fifth redistribution pattern RP5(G) for a ground grid pattern. The fifth redistribution pattern RP5(G) for a ground grid pattern may extend in a first direction X and a second direction Y, when viewed in plan view, and may have a grid shape. A ground voltage may be applied to the fifth redistribution pattern RP5(G) for a ground grid pattern. The fifth redistribution patterns RP5(B) for bonding pads may be disposed in a plurality of rows in the first direction X and the second direction Y along an edge of the second redistribution substrate RD2.

The marking pattern MP may be disposed on a location where the fifth redistribution patterns RP5 are absent. The marking pattern MP may be spaced apart from the fifth redistribution patterns RP5. The marking pattern MP may be surrounded by the fifth redistribution pattern RP5(G) for a ground grid pattern. The marking pattern MP may be provided in plural, and the plurality of masking patterns MP may be spaced apart from each other. FIG. 1 depicts that the marking pattern MP has a rectangular shape when viewed in plan view. Embodiments, however, are not limited thereto, and the marking pattern MP may have a circular shape, an oval shape, a polygonal shape, or any other suitable shape when viewed in plan view.

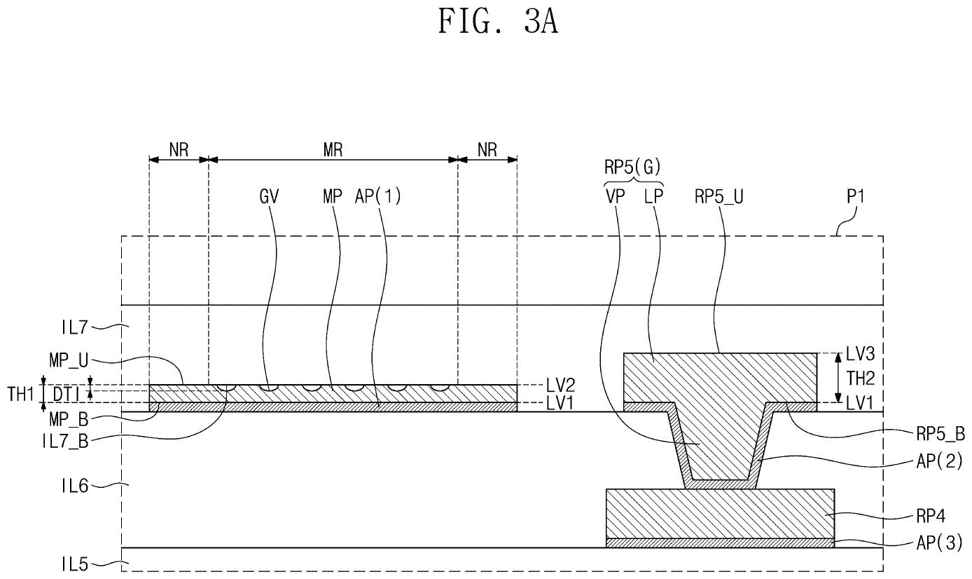

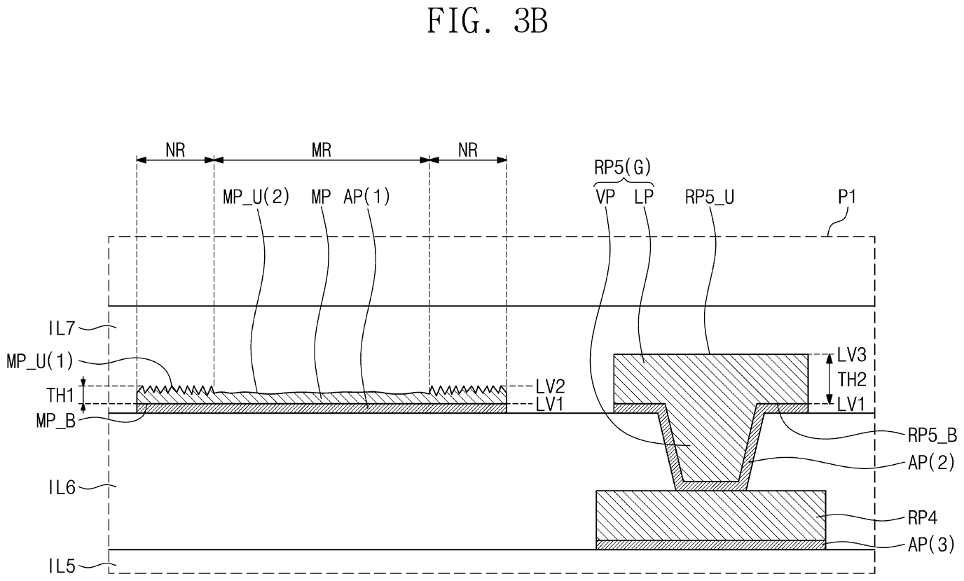

FIGS. 3A and 3B illustrate enlarged views showing section P1 of FIG. 2 according to one or more example embodiments.

Referring to FIGS. 2 and 3A, each of the fifth redistribution patterns RT5 may include at least one selected from: a via part VP that is inserted into the sixth redistribution dielectric layer IL6 and a line part LP (and/or a pad part PP) that upwardly protrudes from the sixth redistribution dielectric layer IL6.

The marking pattern MP may have a bottom surface MP_B located at a first level LV1. The line part LP (and/or the pad part PP) of the fifth redistribution pattern RT5 may have a bottom surface RP5_B located at the first level LV1. A top surface MP_U of the marking pattern MP may be located at a second level LV2 higher than the first level LV1. A top surface RP5_U of the fifth redistribution pattern RT5 may be located at a third level LV3 higher than the second level LV2. The marking pattern MP may have a first thickness TH1. The line part LP (and/or the pad part PP) of the fifth redistribution pattern RT5 may have a second thickness TH2 greater than the first thickness TH1. The marking pattern MP may include the same conductive material (e.g., copper) as that of the fifth redistribution pattern RT5.

Referring to FIG. 3A, the marking pattern MP may include a marking region where a mark (see MK of FIG. 1) is formed and a non-marking region NR where the mark MK is not formed. On the marking region MR, a plurality of grooves GV may be formed on the top surface MP_U of the marking pattern MP. It may therefore be possible to secure visibility. The grooves GV may be connected to form numerals, alphabets, and/or symbols, and these may constitute the mark MK of FIG. 1.

Referring to FIG. 3A, each of the grooves GV may have a first depth DT1. The first depth DT1 may be about 0.01 to 0.5 times the first thickness TH1. The first depth DT1 may range from, for example, about 1 μm to about 8 μm. A floor of each of the grooves GV may be spaced apart from a bottom surface IL7_B of the seventh redistribution dielectric layer IL7. Each of the grooves GV may be an empty space.

The adhesive pattern AP may be provided in plural. The adhesive patterns AP may include first, second, and third adhesive patterns AP(1), AP(2), and AP(3). The first adhesive pattern AP(1) may be disposed below the marking pattern MP, and the second adhesive pattern AP(2) may cover the bottom surface of the fifth redistribution pattern RP5. The third adhesive pattern AP(3) may cover a bottom surface of the fourth redistribution pattern RP4. The first, second and third adhesive patterns AP(1), AP(2) and AP(3) may have the same thickness and may include the same conductive material (e.g., titanium).

Alternatively, referring to FIG. 3B, the non-marking region NR may have a first top surface MP_U(1) having a first surface roughness. The marking region MR may have a second top surface MP_U(2) having a second surface roughness less than the first surface roughness. The surface roughness may refer to an arithmetical average roughness (Ra). A difference between the first surface roughness and the second surface roughness may lead to a difference in reflectance to recognize the mark MK. It may therefore be possible to secure visibility. Other structural features may be identical or similar to those discussed with reference to FIG. 3A.

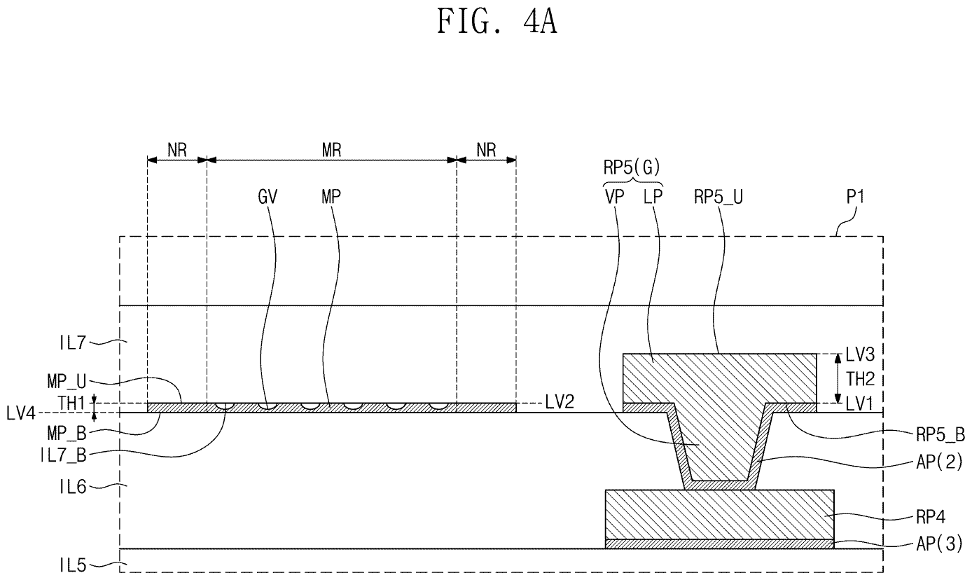

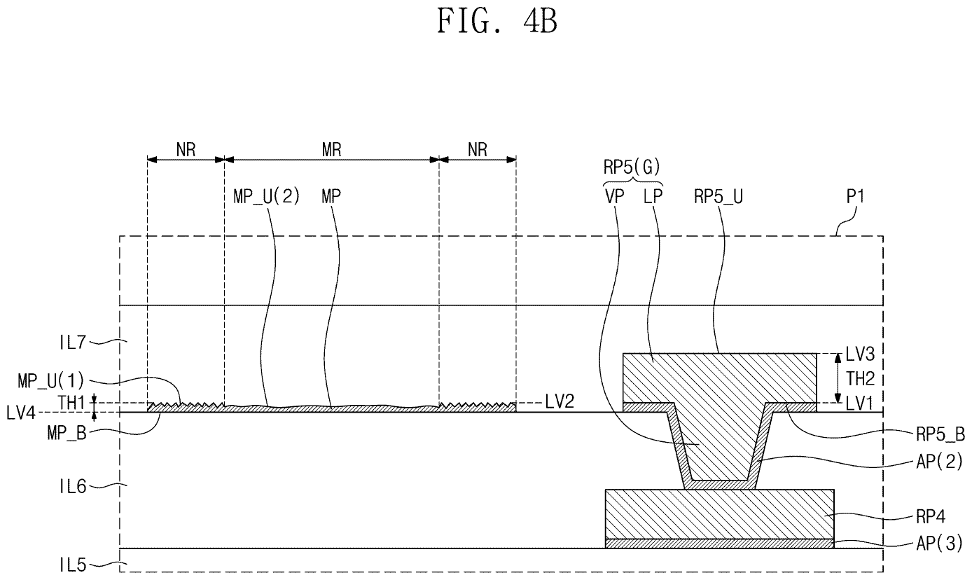

FIGS. 4A and 4B illustrate enlarged views showing section P1 of FIG. 2 according to one or more example embodiments.

Referring to FIG. 4A, the first adhesive pattern AP(1) of FIG. 3A may be absent below the marking pattern MP. The bottom surface MP_B of the marking pattern MP may be in contact with the sixth redistribution dielectric layer IL6 and located at a fourth level LV4. The fourth level LV4 of the bottom surface MP_B of the marking pattern MP may be lower than the first level LV1 of the bottom surface RP5_B of the line part LP (and/or the pad part PP) included in the fifth redistribution pattern RT5. The top surface MP_U of the marking pattern MP may be located at a level the same as the first level LV1 of the bottom surface RP5_U of the line part LP (and/or the pad part PP) included in the fifth redistribution pattern RT5. The first thickness TH1 of the marking pattern MP may be the same as a thickness of the second adhesive pattern AP(2) that surrounds the bottom surface of the fifth redistribution pattern RT5. The marking pattern MP may include the same conductive material (e.g., titanium) as that of the second adhesive pattern AP(2). A plurality of grooves GV may be formed on an upper portion of the marking pattern MP. Other structural features may be identical or similar to those discussed with reference to FIG. 3A.

Alternatively, referring to FIG. 4B, the marking pattern MP in contact with the sixth redistribution dielectric layer IL6 may have a first surface roughness on the non-marking region NR and a second surface roughness, which is less than the first surface roughness, on the marking region MR. Other configurations may be identical or similar to those discussed with reference to FIGS. 3B and 4A.

According to one or more example embodiments, the fifth, sixth and seventh redistribution dielectric layers IL5, IL6 and IL7 of the second redistribution substrate RD2 may all be formed of a photo-imageable dielectric (PID), and thus fine patterns may be formed to achieve a highly integrated semiconductor package. In addition, no marking pattern may be disposed on an uppermost redistribution dielectric layer of the second redistribution substrate RD2, and thus the semiconductor package may have a reduced overall thickness.

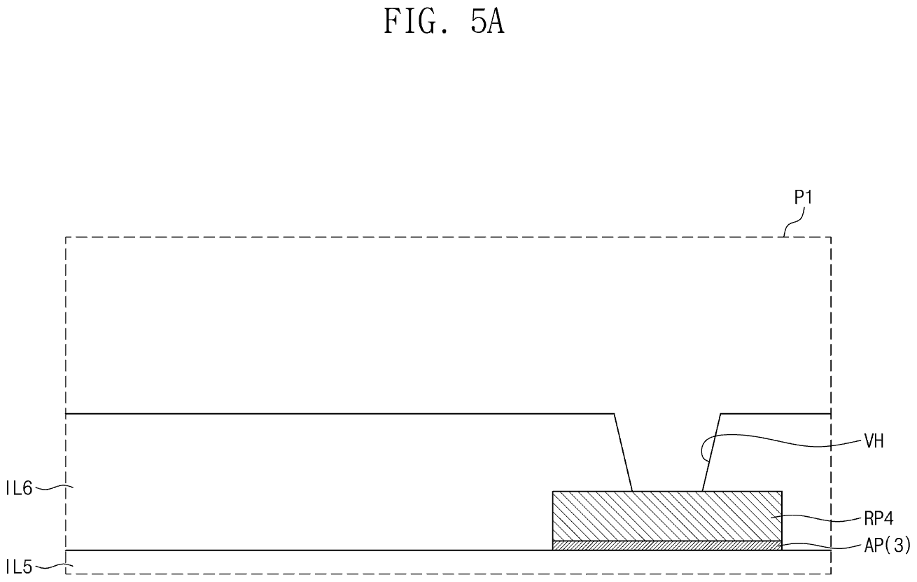

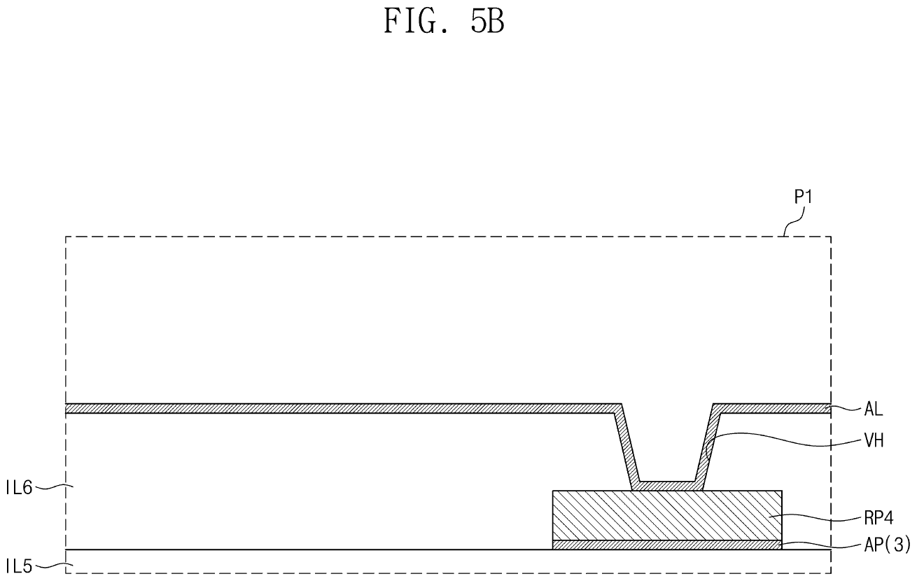

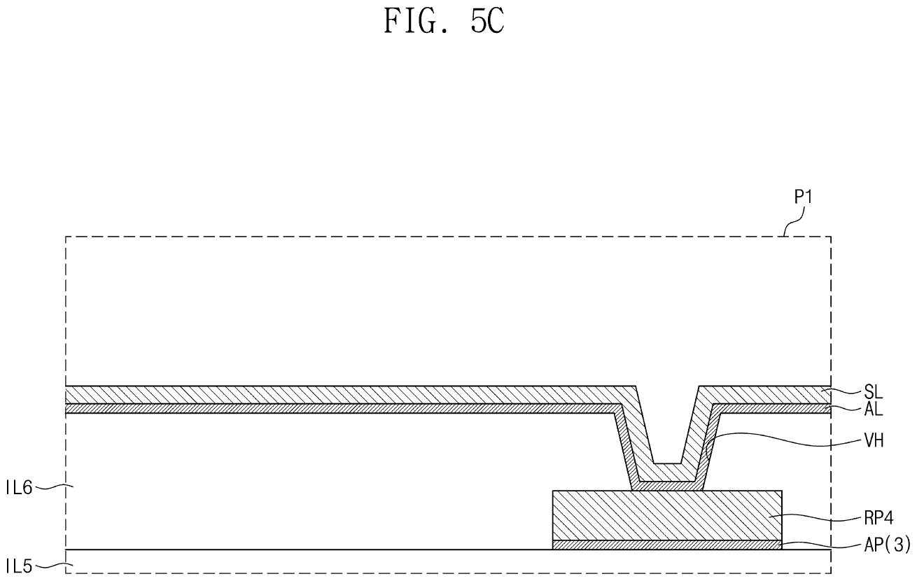

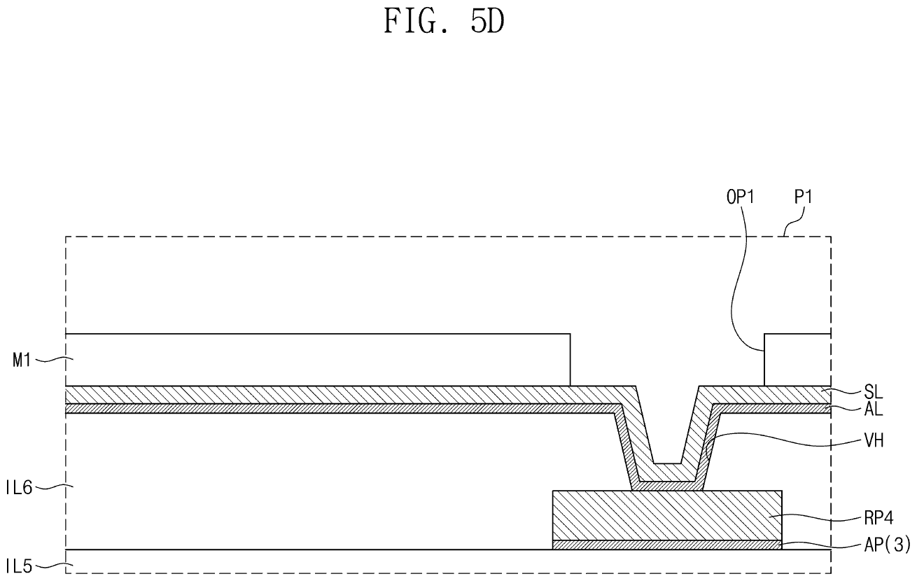

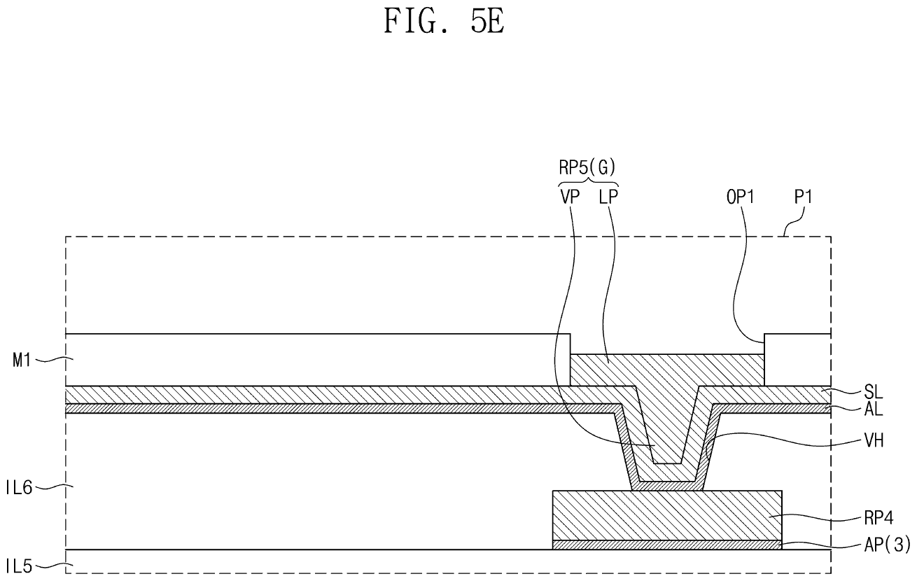

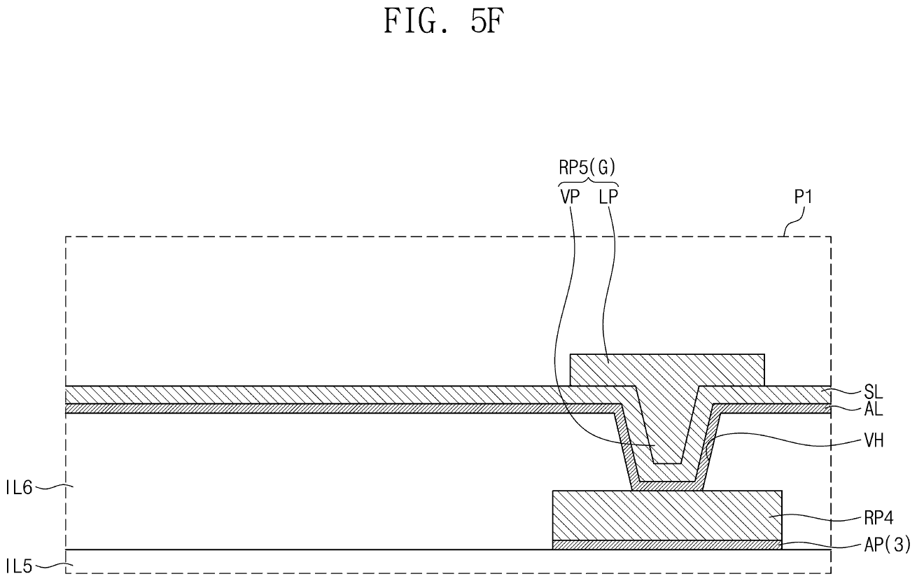

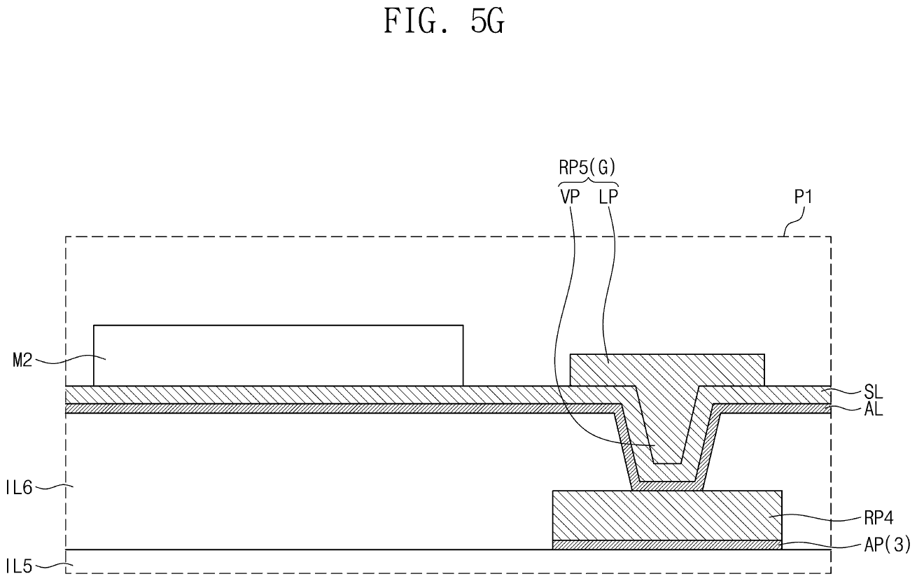

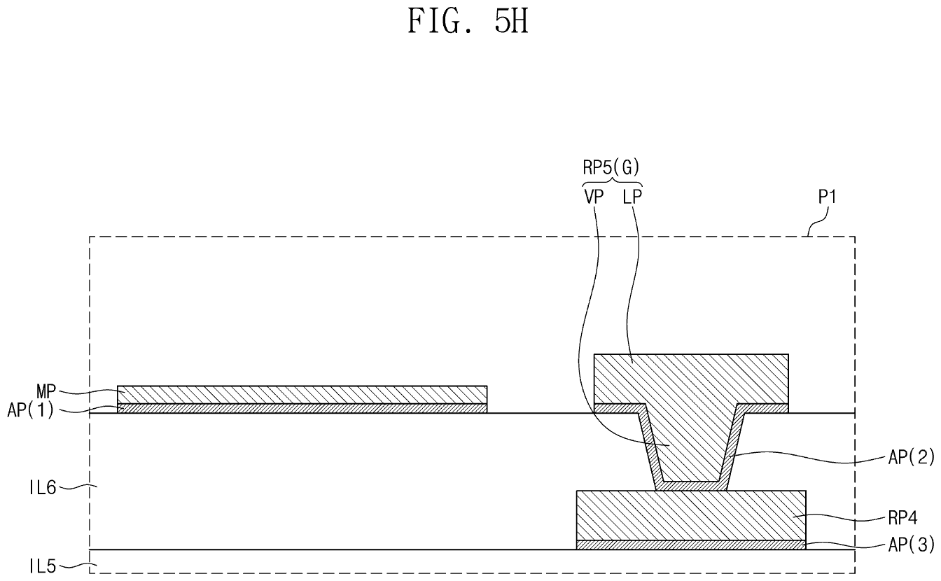

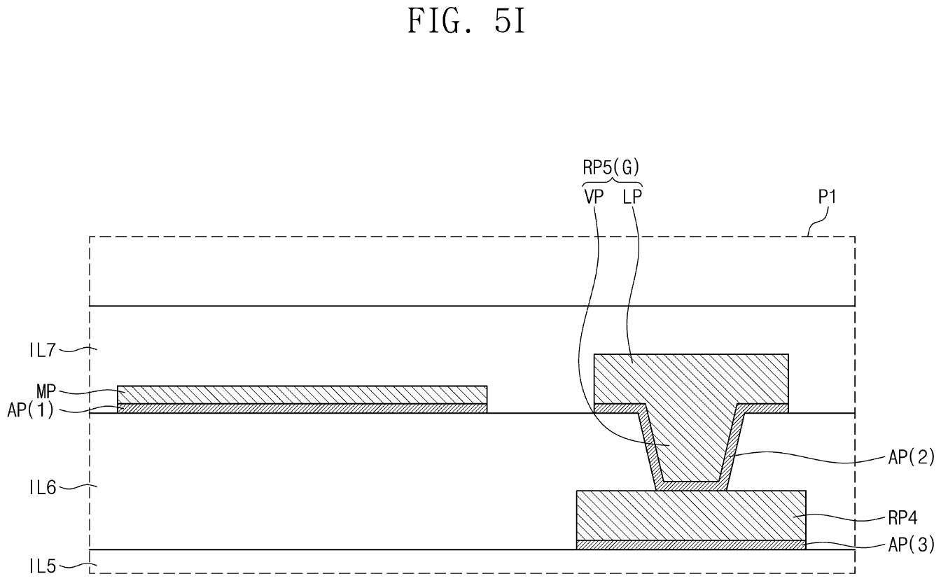

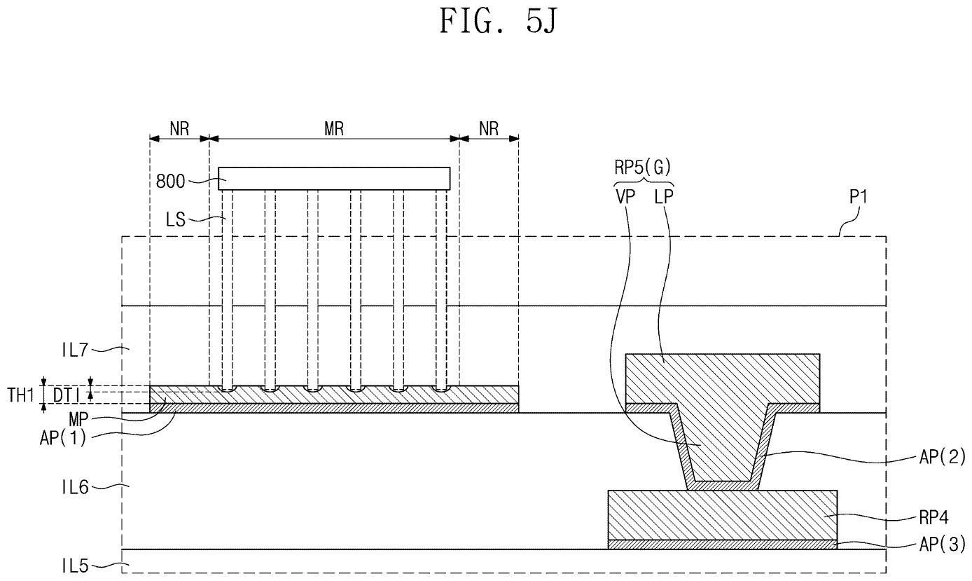

FIGS. 5A, 5B, 5C, 5D, 5E, 5F, 5G, 5H, 5I and 5J illustrate cross-sectional views showing a method of fabricating a semiconductor package of FIG. 3A.

Referring to FIG. 2, an ordinary semiconductor fabrication process may be employed to manufacture a first redistribution substrate RD1. If a first redistribution dielectric layer IL1 is formed of an opaque ajinomoto build-up film (ABF) when the first redistribution substrate RD1 is manufactured, a laser may be used to form holes on the first redistribution dielectric layer IL1. Second, third and fourth redistribution dielectric layers IL2, IL3 and IL4 may be formed of a transparent photo-imageable dielectric (PID), and in this case, coating, bake, exposure, and development processes (or a photolithography process) may be performed to form holes on the second, third and fourth redistribution dielectric layers IL2, IL3 and IL4. A deposition process may be performed to form adhesive patterns AP, and a plating process may be performed to form under bumps UBM and first, second and third redistribution pattern RP1, RP2 and RP3. A connection substrate 900 and a first semiconductor device CH1 may be mounted on the first redistribution substrate RD1. A first mold layer MD1 may be formed to cover the first redistribution substrate RD1, the connection substrate 900, and the first semiconductor device CH1. A fifth redistribution dielectric layer IL5 may be formed on the first mold layer MD1. A third adhesive pattern AP(3) and fourth redistribution patterns RP4 may be formed on the fifth redistribution dielectric layer IL5.

Referring to FIG. 5A, a sixth redistribution dielectric layer IL6 may be formed to cover the fifth redistribution dielectric layer IL5 and the fourth redistribution patterns RP4. The sixth redistribution dielectric layer IL6 may be formed of a photo-imageable dielectric (PID). The sixth redistribution dielectric layer IL6 may be formed by performing coating, bake, exposure, and development (or photolithography) processes on a photo-imageable dielectric layer. A via hole VH exposing the fourth redistribution pattern RP4 may be formed on the sixth redistribution dielectric layer IL6. Because the sixth redistribution dielectric layer IL6 is formed of a photo-imageable dielectric (PID) layer having a photosensitive material, the via hole VH may be formed through a photolithography process. Therefore, a fine pattern may be formed on the sixth redistribution dielectric layer IL6. As a result, a semiconductor package may achieve high integration.

Referring to FIG. 5B, an adhesive layer AL may be conformally formed on a front surface of the sixth redistribution dielectric layer IL6. The adhesive layer AL may be formed of, for example, a titanium layer. The adhesive layer AL may be formed by atomic layer deposition (ALD), chemical vapor deposition (CVD), physical vapor deposition (PVD), or sputtering. The adhesive layer AL may cover an inner wall of the via hole VH and a top surface of the fourth redistribution pattern RP4.

Referring to FIG. 5C, a seed layer SL may be conformally formed on the adhesive layer AL. The seed layer SL may be formed of, for example, a copper layer. The seed layer SL may be formed by atomic layer deposition (ALD), chemical vapor deposition (CVD), physical vapor deposition (PVD), or sputtering. The seed layer SL may cover the inner wall of the via hole VH and the top surface of the fourth redistribution pattern RP4. The adhesive layer AL may assist deposition of copper, or the seed layer SL, on the sixth redistribution dielectric layer IL6. It may be difficult to deposit copper without the adhesive layer AL on the sixth redistribution dielectric layer IL6. In addition, the adhesive layer AL may serve to prevent copper, which constitutes the seed layer SL or the fifth redistribution patterns RP5, from diffusing into the sixth redistribution dielectric layer IL6.

Referring to FIG. 5D, a first mask pattern M1 may be formed on the seed layer SL. The first mask pattern M1 may be formed of, for example, a photoresist pattern. The first mask pattern M1 may be formed to have a first opening OP1 that overlaps the via hole VH.

Referring to FIG. 5E, the seed layer SL may be used to perform a plating process to form the fifth redistribution pattern RP5 in the via hole VH and the first opening OP1. As illustrated in FIG. 2, a plurality of fifth redistribution patterns RP5 may be formed. The fifth redistribution patterns RP5 may include fifth redistribution patterns RP5(B) for bonding pads and a fifth redistribution pattern RP5(G) for a ground grid pattern. The fifth redistribution pattern RP5 may include a via part VP in the via hole VH and a line part LP (and/or a pad part PP) in the first opening OP1. The fifth redistribution pattern RP5 may be formed of the same conductive material (e.g., copper) as that of the seed layer SL, and in this case, an invisible boundary may be present between the fifth redistribution pattern RP5 and the seed layer SL.

Referring to FIG. 5F, the first mask pattern M1 may be removed to expose a top surface of the seed layer SL. When the first mask pattern M1 is formed of a photoresist pattern, an ashing process may be performed to remove the first mask pattern M1.

Referring to FIG. 5G, a second mask pattern M2 may be formed on the seed layer SL. The second mask pattern M2 may be formed of, for example, a photoresist pattern. The second mask pattern M2 may be spaced apart from the fifth redistribution pattern RP5. The second mask pattern M2 may limit a position and shape of a marking pattern MP which will be discussed below.

Referring to FIGS. 5G and 5H, the second mask pattern M2 and the fifth redistribution pattern RP5 may be used as an etching mask to remove the seed layer SL and the adhesive layer AL on a side of the second mask pattern M2 and the fifth redistribution pattern RP5 and to expose a top surface of the sixth redistribution dielectric layer IL6. In this stage, a portion of the adhesive layer AL may be changed into a first adhesive pattern AP(1) and a second adhesive pattern AP(2). In addition, a portion of the seed layer SL may be changed into a marking pattern MP. Another portion of the seed layer SL, which is positioned below the fifth redistribution pattern RP5, and the fifth redistribution pattern RP5 may be brought together to constitute a portion of the fifth redistribution pattern RP5.

Referring to FIG. 5I, a seventh redistribution dielectric layer IL7 may be formed to cover the marking pattern MP, the fifth redistribution pattern RP5, and the sixth redistribution dielectric layer IL6. The seventh redistribution dielectric layer IL7 may be formed of a photo-imageable dielectric (PID). The seventh redistribution dielectric layer IL7 may be formed by coating, baking, exposing, and developing a photo-imageable dielectric layer. The seventh redistribution dielectric layer IL7 may be transparent. The seventh redistribution dielectric layer IL7 may expose top surfaces of the fifth redistribution patterns RP5(B) for bonding pads. Because the seventh redistribution dielectric layer IL7 is formed of a photo-imageable dielectric (PID) layer having a photosensitive material, a fine pattern may be formed on the seventh redistribution dielectric layer IL7. As a result, a semiconductor package may achieve high integration.

Referring to FIG. 5J, a laser LS may be irradiated from a laser generator 800 such that the laser LS may pass through the seventh redistribution dielectric layer IL7 to form grooves GV having a first depth DT1 on the marking pattern MP. The first depth DT1 may be about 0.01 to 0.5 times a first thickness TH1 of the marking pattern MP.

Alternatively, as illustrated in FIG. 3B, the laser LS may be used to reduce a surface roughness of a top surface MP_U(2) of a marking region MR included in the marking pattern MP. A surface roughness of a top surface MP_U(1) of a non-marking region NR where the laser LS is not irradiated may be relatively greater than the surface roughness of the top surface MP_U(2) of the marking region MR where the laser LS is irradiated.

Because the seventh redistribution dielectric layer IL7 is transparent in the step of FIG. 5J, the laser LS may penetrate the seventh redistribution dielectric layer IL7. However, the marking pattern MP may include metal and be opaque to absorb the laser LS. Thus, a mark MK may be engraved on the marking pattern MP. The laser LS may have, for example, a green wavelength of visible light. For example, the laser LS may have a wavelength of about 520 nm to about 550 nm. In this way, the mark MK may be displayed on a semiconductor package 1000.

The marking pattern MP of FIGS. 4A and 4B may be formed with a portion of the adhesive layer AL of FIG. 5B. Before the formation of the seed layer SL of FIG. 5C, the second mask pattern M2 of FIG. 5G may be formed on the adhesive layer AL of FIG. 5B.

As a semiconductor device becomes highly integrated, it may be required that a photo-imageable dielectric (PID) capable of being finely patterned should be used to form all of redistribution dielectric layers IL5, IL6 and IL7 included in the second redistribution substrate RD2. However, the photo-imageable dielectric (PID) may be transparent such that no laser may be absorbed to cause difficulty in forming a mark on the photo-imageable dielectric (PID). In contrast, in a method of fabricating a semiconductor package according to one or more example embodiments, the marking pattern MP may be formed with a portion of the seed layer SL or a portion of the adhesive layer AL, and the mark MK may be formed on the marking pattern MP. Accordingly, it may be possible to achieve a highly integrated semiconductor package capable of being finely patterned.

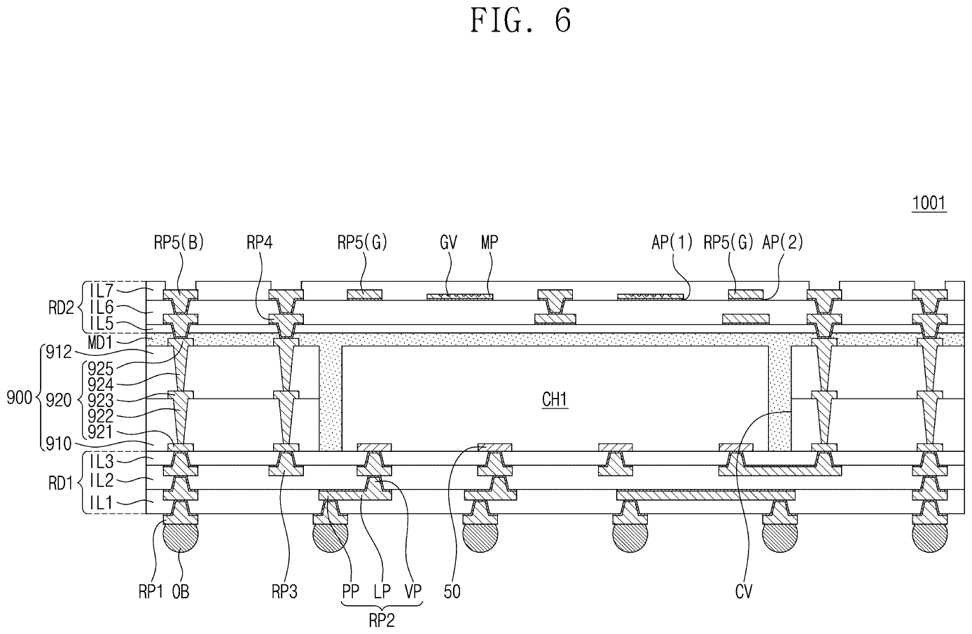

FIG. 6 illustrates a cross-sectional view showing a semiconductor package according to one or more example embodiments.

Referring to FIG. 6, in a semiconductor package 1001 according to one or more example embodiments, the first redistribution substrate RD1 may include first, second and third redistribution dielectric layers IL1, IL2 and IL3 that are sequentially stacked. The first redistribution substrate RD1 may include none of the fourth redistribution dielectric layer IL4 and the under bump UBM of FIG. 2. The via parts VP of the first, second and third redistribution patterns RP1, RP2 and RP3 may be positioned on the line parts LP and/or the pad parts PP of the first, second and third redistribution patterns RP1, RP2 and RP3. A width of the via part VP may decrease in an upward direction. External connection terminals OB may be bonded to bottom surfaces of the first redistribution patterns RP1. The first semiconductor device CH1 and the first redistribution substrate RD1 may be in direct contact with each other without the first inner connection members IB1 or the second inner connection members IB2. The chip pads 50 of the first semiconductor device CH1 may be adjacent to the via parts VP of the third redistribution patterns RP3. Other configurations may be identical or similar to those discussed with reference to FIGS. 1, 2, 3A, 3B, 4A and 4B.

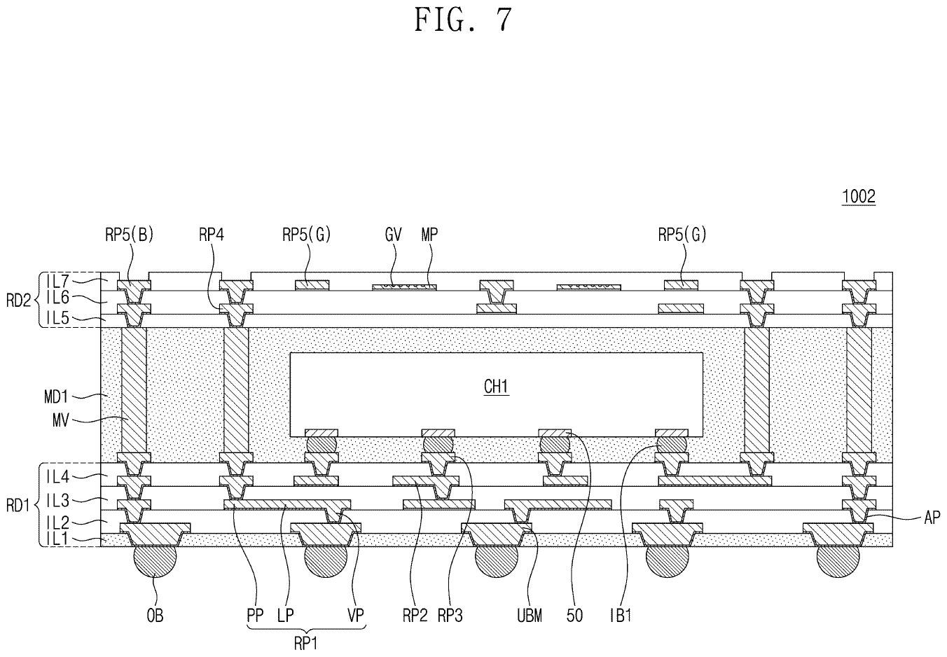

FIG. 7 illustrates a cross-sectional view showing a semiconductor package according to one or more example embodiments.

Referring to FIG. 7, a semiconductor package 1002 according to one or more example embodiments may not include the connection substrate 900 of FIG. 2. Mold vias MV may penetrate the first mold layer MD1 to connect the first redistribution substrate RD1 to the second redistribution substrate RD2. The mold vias MV may include, for example, copper. Other configurations may be identical or similar to those discussed with reference to FIGS. 1, 2, 3A, 3B, 4A and 4B.

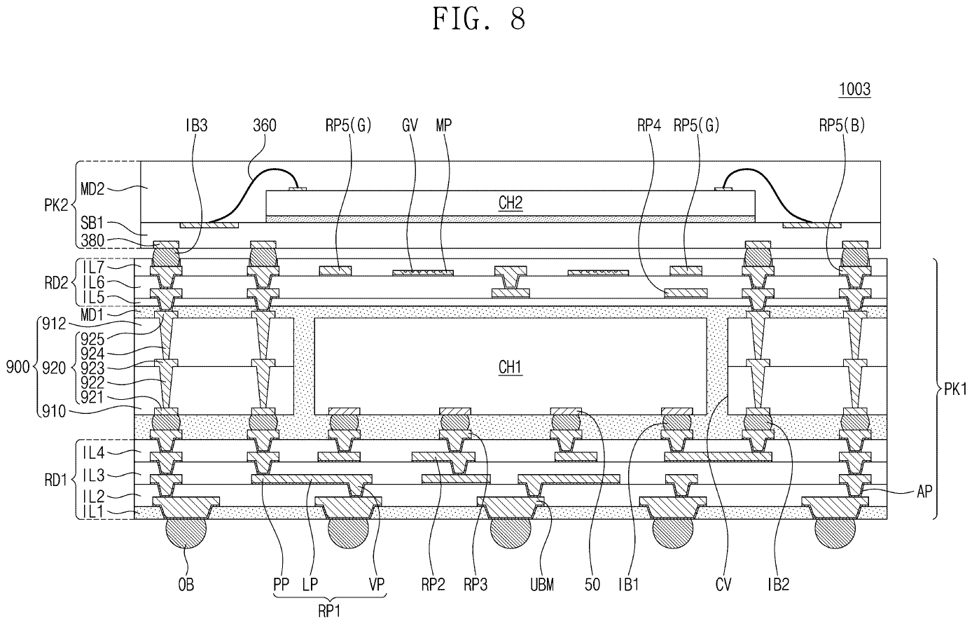

FIG. 8 illustrates a cross-sectional view showing a semiconductor package according to one or more example embodiments.

Referring to FIG. 8, a semiconductor package 1003 according to one or more example embodiments may have a package-on-package structure in which a second sub-package package PK2 is mounted on a first sub-package PK1. The first sub-package PK1 may have a structure the same as or similar to that discussed with reference to FIGS. 1, 2, 3A, 3B, 4A and 4B. The second sub-package PK2 may include a package substrate SB1, a second semiconductor device CH2 mounted on the package substrate SB1, and a second mold layer MD2 that covers the second semiconductor device CH2. The package substrate SB1 may be, for example, a bi-layered or multi-layered printed circuit board. The second semiconductor device CH2 may be connected through wires 360 to the package substrate SB1. Substrate lower conductive pads 380 disposed on a bottom surface of the package substrate SB1 may be connected through third inner connection members IB3 to the fifth redistribution patterns RP5(B) for bonding pads. Each of the third inner connection members IB3 may include at least one selected from: a solder ball, a conductive bump, and a conductive pillar. Each of the third inner connection members IB3 may include at least one selected from: tin, lead, silver, aluminum, gold, and nickel.

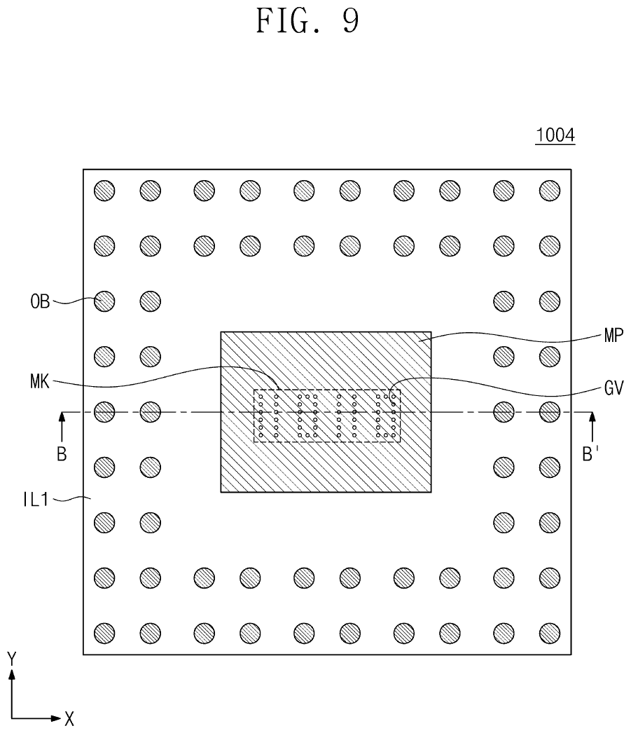

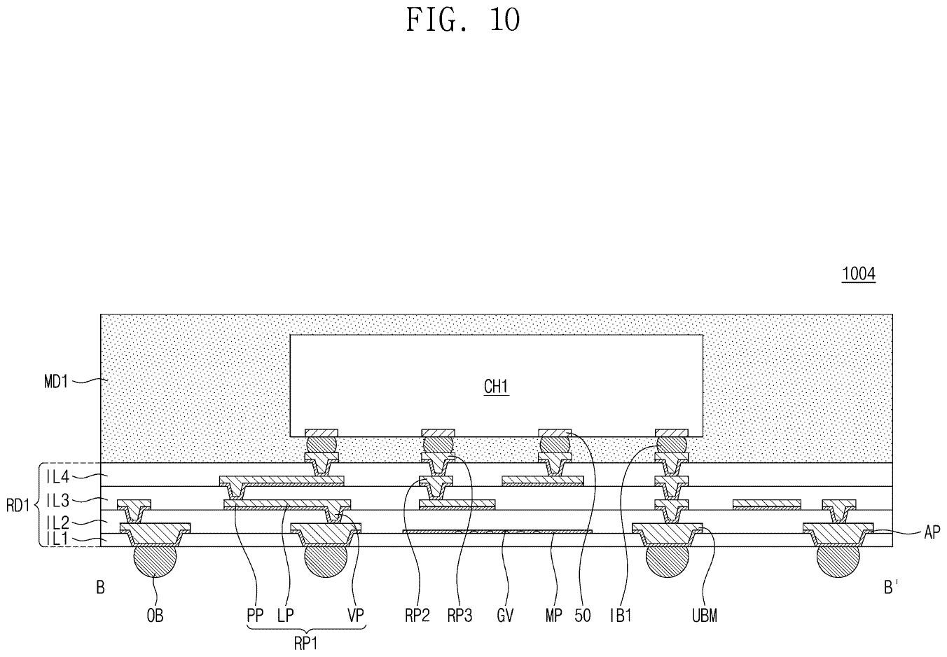

FIG. 9 illustrates a bottom plan view showing a semiconductor package according to one or more example embodiments. FIG. 10 illustrates a cross-sectional view taken along line B-B′ of FIG. 9 according to one or more example embodiments.

Referring to FIGS. 9 and 10, a semiconductor package 1004 according to one or more example embodiments may include a first redistribution substrate RD1, a first semiconductor device CH1, and a first mold layer MD1. External connection terminals OB may be two-dimensionally arranged along a first direction X and a second direction Y below the first redistribution substrate RD1. The external connection terminals OB may be arranged in a plurality of rows along an edge of the first redistribution substrate RD1.

The first redistribution substrate RD1 may include sequentially stacked first, second, third and fourth redistribution dielectric layers IL1, IL2, IL3 and IL4, under bumps UBM, first, second and third redistribution patterns RP1, RP2 and RP3, and a marking pattern MP. Each of the first, second, third and fourth redistribution dielectric layers IL1, IL2, IL3 and IL4 may be transparent and formed of a photo-imageable dielectric (PID). The marking pattern MP may be formed between the first redistribution dielectric layer IL1 and the second redistribution dielectric layer IL2. The marking pattern MP may be covered with the first redistribution dielectric layer IL1 disposed at bottom of the first, second, third and fourth redistribution dielectric layers IL1, IL2, IL3 and IL4 of the first redistribution substrate RD1.

The marking pattern MP may be formed to have the same material and thickness as those of an adhesive pattern AP that covers a bottom surface of the under bump UBM. A plurality of grooves GV may be formed on the bottom surface of the marking pattern MP. Alternatively, as illustrated in FIG. 4B, a surface roughness of the bottom surface on the marking region MR of the marking pattern MP may be different from a surface roughness of the bottom surface on the non-marking pattern MP of the marking pattern MP.

In a semiconductor package according to one or more example embodiments, a photo-imageable dielectric (PID) may be used to form all of redistribution dielectric layers of a second redistribution substrate, and thus a fine pattern may be formed to achieve a highly integrated semiconductor package. In addition, in the semiconductor package according to one or more example embodiments, no marking pattern may be disposed on an uppermost redistribution dielectric layer of the second redistribution substrate, and thus the semiconductor package may have a reduced overall thickness.

In a method of fabricating a semiconductor package according to one or more example embodiments, even when an uppermost layer may be formed with a transparent photo-imageable dielectric (PID) capable of being finely patterned, a portion of a seed layer or a portion of an adhesive layer may be used as a marking pattern to display a mark.

Although one or more example embodiments have been particularly shown and described above in connection with one or more example embodiments illustrated in the accompanying drawings, it will be apparent to those skilled in the art that various changes and modifications in form and details may be made therein without departing from the spirit and scope of the following claims.

1. A semiconductor package comprising:
a first redistribution substrate;
a semiconductor device on the first redistribution substrate;
a mold layer that covers the first redistribution substrate and the semiconductor device; and
a second redistribution substrate on the mold layer,
wherein the second redistribution substrate comprises:
a first redistribution dielectric layer;
a redistribution pattern on the first redistribution dielectric layer;
a marking pattern on the first redistribution dielectric layer and spaced apart from the redistribution pattern; and
a second redistribution dielectric layer that covers the marking pattern,
wherein a bottom surface of the marking pattern a bottom surface of the redistribution pattern are at a same level, and
wherein a top surface of the marking pattern is at a level which is lower than a level of a top surface of the redistribution pattern.

2. The semiconductor package of claim 1, wherein the second redistribution dielectric layer is transparent.

3. The semiconductor package of claim 1, wherein the marking pattern comprises a plurality of grooves on the top surface of the marking pattern.

4. The semiconductor package of claim 3, wherein the marking pattern has a first thickness, and
wherein each one of the plurality of grooves has a depth that is about 0.1 to 0.5 times the first thickness.

5. The semiconductor package of claim 3, wherein a floor of each one of the plurality of grooves is spaced apart from a bottom surface of the second redistribution dielectric layer.

6. The semiconductor package of claim 1, wherein the marking pattern comprises a marking region and a non-marking region, and
wherein a surface roughness of a top surface of the marking region is different from a surface roughness of a top surface of the non-marking region.

7. The semiconductor package of claim 1, wherein the marking pattern and the redistribution pattern comprise a same material.

8. The semiconductor package of claim 1, wherein the second redistribution substrate further comprises an adhesive pattern between the redistribution pattern and the first redistribution dielectric layer,
wherein the redistribution pattern comprises a first metal, and
wherein the marking pattern and the adhesive pattern comprise a second metal that is different from the first metal.

9. The semiconductor package of claim 8, wherein a thickness of the marking pattern is the same as a thickness of the adhesive pattern.

10. The semiconductor package of claim 1, further comprising a mold via that penetrates the mold layer and connects the first redistribution substrate to the second redistribution substrate.

11. The semiconductor package of claim 1, further comprising a connection substrate on the first redistribution substrate,
wherein the semiconductor device is inserted into a cavity of the connection substrate, and
wherein the mold layer covers the connection substrate.

12. A semiconductor package comprising:
a first redistribution substrate;
a semiconductor device on the first redistribution substrate;
a mold layer that covers the first redistribution substrate and the semiconductor device; and
a second redistribution substrate on the mold layer,
wherein the second redistribution substrate comprises:
a first redistribution dielectric layer;
a redistribution pattern on the first redistribution dielectric layer;
a marking pattern on the first redistribution dielectric layer and spaced apart from the redistribution pattern; and
a second redistribution dielectric layer that covers the marking pattern,
wherein the second redistribution dielectric layer is transparent, and
wherein a thickness of the marking pattern is less than a thickness of the redistribution pattern.

13. The semiconductor package of claim 12, wherein the marking pattern comprises a plurality of grooves on a top surface of the marking pattern.

14. The semiconductor package of claim 13, wherein each of the plurality of grooves has a depth that is about 0.1 to 0.5 times the thickness of the marking pattern.

15. The semiconductor package of claim 13, wherein a floor of each of the plurality of grooves is spaced apart from a bottom surface of the second redistribution dielectric layer.

16. The semiconductor package of claim 12, wherein the marking pattern comprises a marking region and a non-marking region, and
wherein a surface roughness of a top surface of the marking region is different from a surface roughness of a top surface of the non-marking region.

17. A semiconductor package comprising:
a first redistribution substrate;
a plurality of external connection terminals bonded to a lower portion of the first redistribution substrate;
a semiconductor device on the first redistribution substrate;
a mold layer that covers the first redistribution substrate and the semiconductor device;
a second redistribution substrate on the mold layer; and
a connection member in the mold layer and connecting the first redistribution substrate to the second redistribution substrate,
wherein the second redistribution substrate comprises:
a first redistribution dielectric layer;
a redistribution pattern on the first redistribution dielectric layer;
a marking pattern on the first redistribution dielectric layer and spaced apart from the redistribution pattern; and
a second redistribution dielectric layer that covers the marking pattern,
wherein the first redistribution dielectric layer and the second redistribution dielectric layer are transparent,
wherein the marking pattern comprises a marking region and a non-marking region, and
wherein a surface roughness of a top surface of the marking region is different from a surface roughness of a top surface of the non-marking region.

18. The semiconductor package of claim 17, wherein the surface roughness of the top surface of the marking region is less than the surface roughness of the top surface of the non-marking region.

19. The semiconductor package of claim 17, wherein a thickness of the marking pattern is less than a thickness of the redistribution pattern.

20. The semiconductor package of claim 17, wherein the second redistribution substrate further comprises:
a first adhesive pattern between the marking pattern and the first redistribution dielectric layer; and
a second adhesive pattern between the redistribution pattern and the first redistribution dielectric layer.

21. (canceled)
